(19) United States
(12) Patent Application Publication
(10) Pub. No.: US 2026/0190821 A1
(43) Pub. Date: Jul. 2, 2026

(54) DISPLAY DEVICE AND ELECTRONIC DEVICE INCLUDING THE SAME

(71) Applicant: Samsung Display Co., LTD., Yongin-si (KR)

(72) Inventors: Changwook KIM, Yongin-si (KR); Chan Young KIM, Yongin-si (KR); Choong Youl IM, Yongin-si (KR); BEOHMROCK CHOI, Yongin-si (KR)

(21) Appl. No.: 19/179,216

(22) Filed: Apr. 15, 2025

(30) Foreign Application Priority Data
Sep. 5, 2024 (KR) 10-2024-0120767

(51) Int. Cl. H10K 59/80; H10K 59/122; H10K 59/35; H10K 59/38

(52) U.S. Cl. CPC H10K 59/8792; H10K 59/122; H10K 59/352; H10K 59/38

(57) ABSTRACT

A display device includes: a substrate; a transistor disposed on the substrate; a first electrode electrically connected with the transistor; a pixel defining layer disposed on the first electrode; a light-emitting layer disposed in an opening of the pixel defining layer; a second electrode disposed on the light-emitting layer; an encapsulation layer disposed on the second electrode; and a main light-blocking layer and a sub-blocking layer disposed on the encapsulation layer, in which a first distance between an inner edge of the sub-blocking layer and an edge of the pixel defining layer satisfies Equation 1, and a second distance between an outer edge of the sub-blocking layer and the edge of the pixel defining layer satisfies Equation 2.

This application claims priority to Korean Patent Application No. 10-2024-0120767, filed on Sep. 5, 2024, and all the benefits accruing therefrom under 35 U.S.C. § 119, the content of which in its entirety is herein incorporated by reference.

### BACKGROUND

### (a) Field

The disclosure relates to a display device.

### (b) Description of the Related Art

A display device is a device that displays an image, and includes a liquid crystal display (“LCD”), an organic light-emitting diode (“OLED”), or the like. These display devices are used in a variety of electronic devices, such as cell phones, navigation systems, digital cameras, e-books, portable gaming devices, or other terminals.

### SUMMARY

The disclosure attempts to provide a display device that is capable of tuning colors.

An embodiment of the disclosure provides a display device including: a substrate; a transistor disposed on the substrate; a first electrode electrically connected with the transistor; a pixel defining layer disposed on the first electrode; a light-emitting layer disposed in an opening of the pixel defining layer; a second electrode disposed on the light-emitting layer; an encapsulation layer disposed on the second electrode; and a main light-blocking layer and a sub-blocking layer disposed on the encapsulation layer, in which a first distance between an inner edge of the sub-blocking layer and an edge of the pixel defining layer satisfies Equation 1, and a second distance between an outer edge of the sub-blocking layer and the edge of the pixel defining layer satisfies following Equation 2.

$${\sum }_{n = N}^{1} {d}_{n} ( @ {θ}_{N + 1} = {θ}_{a} ) \qquad Equation 1$$

$${\sum }_{n = N}^{1} {d}_{n} ( @ {θ}_{N + 1} = {θ}_{b} ) \qquad Equation 2$$

In an embodiment, in Equation 1, θₐ is a first angle of light emitted outwardly from the display device, in Equation 2, θ_{b} is a second angle of light emitted outwardly from the display device, the first angle is less than the second angle, in Equations 1 and 2, N is a number of layers disposed between the pixel defining layer and the main light-blocking layer, dₙ in Equation 1 and Equation 2 is determined through following Equation 3, and

$${d}_{n} = {t}_{n} \cdot tan {θ}_{n} \qquad Equation 3$$

in Equation 3, tₙ is a thickness of an n-th layer and θₙ is determined through following Equation 4, and

$${θ}_{n} = {sin}^{- 1} ( sin {θ}_{n + 1} \cdot \frac{{n}_{n + 1}}{{n}_{n}} ) \qquad Equation 4$$

in Equation 4, n_{N+1} is 1.

In an embodiment, the main light-blocking layer and the sub-blocking layer may be spaced apart from each other, and a planar shape of an opening of the main light-blocking layer and a planar shape of the sub-blocking layer may be circular.

In an embodiment, the main light-blocking layer may surround the sub-blocking layer.

In an embodiment, the display device may include a red light-emitting area, a green light-emitting area, and a blue light-emitting area, and the sub-blocking layer may overlap the red light-emitting area.

In an embodiment, the display device may include a red light-emitting area, a green light-emitting area, and a blue light-emitting area, the sub-blocking layer may include at least one of a first sub-blocking layer overlapping the red light-emitting area, a second sub-blocking layer overlapping the green light-emitting area, and a third sub-blocking layer overlapping the blue light-emitting area.

In an embodiment, the sub-blocking layer may include the first sub-blocking layer, the second sub-blocking layer, and the third sub-blocking layer.

In an embodiment, a third distance from a distal end of the pixel defining layer to an inner edge of the first sub-blocking layer in the red light-emitting area may be less than a fourth distance from the distal end of the pixel defining layer to an inner edge of the second sub-blocking layer in the green light-emitting area.

In an embodiment, a fifth distance from a distal end of the pixel defining layer to an inner edge of the first sub-blocking layer in the red light-emitting area may be less than a sixth distance from the distal end of the pixel defining layer to an inner edge of the third sub-blocking layer in the blue light-emitting area.

In an embodiment, the display device may further include a color filter disposed on the main light-blocking layer.

In an embodiment, the color filter may fill a spaced space between the main light-blocking layer and the sub-blocking layer.

Another embodiment of the disclosure provides a display device including: a substrate; a transistor disposed on the substrate; a first electrode electrically connected with the transistor; a pixel defining layer disposed on the first electrode; a light-emitting layer disposed in an opening of the pixel defining layer; a second electrode disposed on the light-emitting layer; an encapsulation layer disposed on the second electrode; and a main light-blocking layer and a sub-blocking layer disposed on the encapsulation layer, in which the sub-blocking layer is disposed within an opening of the main light-blocking layer, planar shapes of the opening of the main light-blocking layer, the sub-blocking layer, and the opening of the pixel defining layer are circular, and the light-emitting layer emits red light.

In an embodiment, a first distance between an inner edge of the sub-blocking layer and an edge of the pixel defining layer may satisfy Equation 1, and a second distance between an outer edge of the sub-blocking layer and the edge of the pixel defining layer may satisfy following Equation 2.

$${\sum }_{n = N}^{1} {d}_{n} ( @ {θ}_{N + 1} = {θ}_{a} ) \qquad Equation 1$$

$${\sum }_{n = N}^{1} {d}_{n} ( @ {θ}_{N + 1} = {θ}_{b} ) \qquad Equation 2$$

In an embodiment, in Equation 1, θₐ is a first angle of light emitted outwardly from the display device, in Equation 2, θ_{b} is a second angle of light emitted outwardly from the display device, the first angle is less than the second angle, in Equations 1 and 2, N is a number of layers disposed between the pixel defining layer and the main light-blocking layer, dₙ in Equation 1 and Equation 2 is determined through following Equation 3, and

$${d}_{n} = {t}_{n} \cdot tan {θ}_{n} \qquad Equation 3$$

in Equation 3, tₙ is a thickness of an n-th layer and θₙ is determined through following Equation 4, and

$${θ}_{n} = {sin}^{- 1} ( sin {θ}_{n + 1} \cdot \frac{{n}_{n + 1}}{{n}_{1}} ) \qquad Equation 4$$

in Equation 4, n_{N+1} is 1.

In an embodiment, the main light-blocking layer may surround the sub-blocking layer.

In an embodiment, the display device may include a red light-emitting area, a green light-emitting area, and a blue light-emitting area.

In an embodiment, the sub-blocking layer may include at least one of a first sub-blocking layer overlapping the red light-emitting area, a second sub-blocking layer overlapping the green light-emitting area, and a third sub-blocking layer overlapping the blue light-emitting area.

In an embodiment, the sub-blocking layer may include the first sub-blocking layer, the second sub-blocking layer, and the third sub-blocking layer.

In an embodiment, a third distance from a distal end of the pixel defining layer to an inner edge of the first sub-blocking layer in the red light-emitting area may be less than a fourth distance from the distal end of the pixel defining layer to an inner edge of the second sub-blocking layer in the green light-emitting area.

In an embodiment, a fifth distance from a distal end of the pixel defining layer to an inner edge of the first sub-blocking layer in the red light-emitting area may be less than a sixth distance from the distal end of the pixel defining layer to an inner edge of the third sub-blocking layer in the blue light-emitting area.

In an embodiment, the display device may further include a color filter disposed on the main light-blocking layer.

In an embodiment, the color filter may fill a spaced space between the main light-blocking layer and the sub-blocking layer.

By the embodiments, it is possible to provide a display device capable of tuning colors.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a schematic perspective view illustrating an embodiment of a state of use of a display device.

FIG. 2 is an exploded perspective view of an embodiment of the display device.

FIG. 3 is a block diagram of an embodiment of the display device.

FIG. 4 is a schematic perspective view of a display device according to another embodiment.

FIG. 5 is a cross-sectional view of an embodiment of a display panel.

FIG. 6 is a top plan view of an embodiment of some components of one pixel.

FIG. 7 and, FIGS. 8A and 8B are cross-sectional views of a traveling path of light in some areas.

FIG. 9 is a cross-sectional view of an embodiment of a display panel.

FIGS. 10A and 10B are each a top plan view of an embodiment of some pixels.

FIG. 11 is a WAD graph according to an Embodiment and a Comparative example.

FIG. 12 is a block diagram of an electronic device.

FIG. 13 shows schematic diagrams of electronic devices according to various embodiments.

### DETAILED DESCRIPTION

In the following detailed description, only illustrative embodiments of the disclosure have been illustrated and described, simply by way of illustration. The disclosure may be variously implemented and is not limited to the following embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the disclosure is not limited thereto. In the drawings, the thickness of layers, films, panels, regions, etc., are exaggerated for clarity. In the drawings, for understanding and ease of description, the thickness of some layers and areas is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “on” another element, it may be directly on the other element or intervening elements may also be present.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “in a plan view”, it means when a target part is viewed from above, and when it is referred to as “in a cross-sectional view”, it means when the cross-section obtained by cutting a target part vertically is viewed from the side.

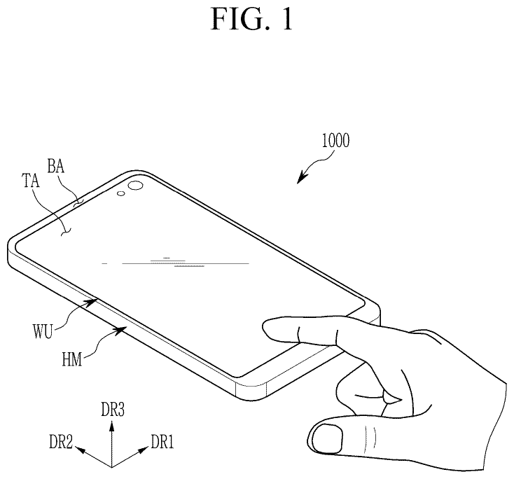

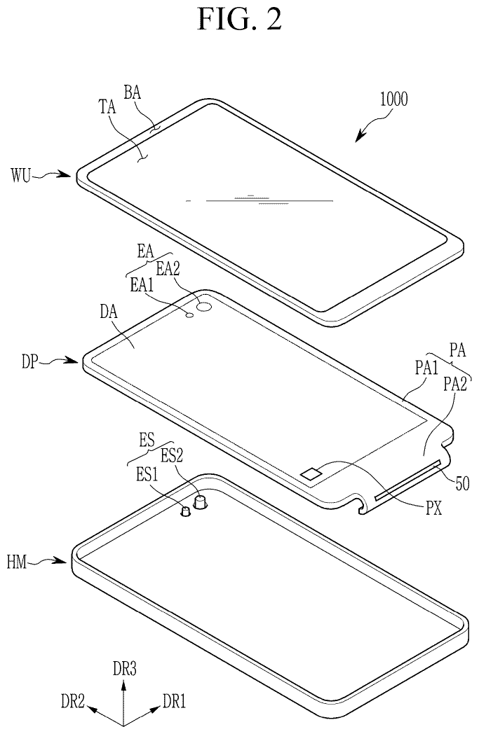

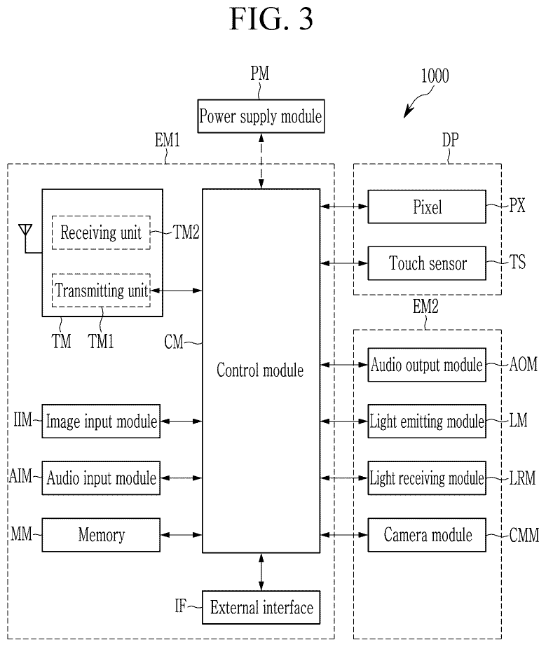

Hereinafter, a schematic structure of a display device will be described with reference to FIGS. 1 to 3. FIG. 1 is a schematic perspective view illustrating an embodiment of a state of use of a display device, FIG. 2 is an exploded perspective view of the display device in the embodiment, and FIG. 3 is a block diagram of the display device in the embodiment.

Referring to FIG. 1, a display device 1000 in an embodiment is a device for displaying video or still images and may be used as a display screen for a variety of products, including portable electronic devices, such as mobile phones, smart phones, tablet personal computers (“PC”), mobile communication terminals, electronic notebooks, e-books, portable multimedia players (“PMPs”), navigation systems, ultra mobile PCs (“UMPCs”), or the like, as well as televisions, laptops, monitors, billboards, and the internet of things (“IoT”). In addition, the display device 1000 in the embodiment may be used in wearable devices, such as smart watches, watch phones, eyewear displays, and head mounted displays (“HMDs”). In addition, the display device 1000 in the embodiment may be used as a center information display (“CID”) placed on an instrument panel of a vehicle, and on a center fascia or dashboard of a vehicle, as a room mirror display in place of a side mirror of a vehicle, and as a display placed on a back surface of a front seat of a vehicle for entertainment for a rear seat of the vehicle. For ease of illustration, FIG. 1 shows the display device 1000 being used as a smart phone.

The display device 1000 may display an image facing a third direction DR3 on a display surface parallel to each of a first direction DR1 and a second direction DR2. The display surface on which the image is displayed may correspond to a front surface of the display device 1000, and may correspond to a front surface of a cover window WU. The image may include a dynamic image as well as a still image.

In the embodiment, a front (or top) surface and a back (or bottom) surface of each member are defined based on the direction in which the image is displayed. The front surface and the back surface are opposed to each other in the third direction DR3, and the normal direction of each of the front surface and the back surface may be parallel to the third direction DR3. A separation distance in the third direction DR3 between the front surface and the back surface may correspond to a thickness in the third direction DR3 of the display panel.

The display device 1000 in the embodiment may detect an externally applied user input (refer to the hand in FIG. 1). The user input may include various forms of external inputs, such as a part of the user's body, light, heat, or pressure. In the embodiment, the user input is illustrated as a user's hand being applied on the front surface. However, the disclosure is not limited thereto. The user input may be provided in a variety of forms, and the display device 1000 may also detect a user input applied to the lateral surface or the back surface of the display device 1000, depending on the structure of the display device 1000.

The display device 1000 may include the cover window WU and a housing HM. In the embodiment, the cover window WU and the housing HM may be coupled with each other to form the exterior appearance of the display device 1000.

The cover window WU may include an insulating panel. In an embodiment, the cover window WU may include or consist of glass, plastic, or any combinations thereof, for example.

A front surface of the cover window WU may define the front surface of the display device 1000. A transmissive area TA may be an optically transparent area. In an embodiment, the transmissive area TA may be an area with about 90% or more visible light transmittance, for example.

A blocking area BA may define the shape of the transmissive area TA. The blocking area BA may be next (adjacent) to the transmissive area TA and may surround the transmissive area TA. The blocking area BA may be an area of relatively low light transmittance compared to the transmissive area TA. The blocking area BA may include an opaque material that blocks light. The blocking area BA may have a predetermined color. The blocking area BA may be defined by a bezel layer provided separately from the transparent substrate defining the transmissive area TA, or may be defined by an ink layer formed by being inserted into or colored by the transparent substrate.

The housing HM may be coupled with the cover window WU. The cover window WU may be disposed on a front surface of the housing HM. The housing HM may be coupled with the cover window WU to provide a predetermined receiving space.

The housing HM may include a material having relatively high rigidity. In an embodiment, the housing HM may include a plurality of frames and/or plates including or consisting of glass, plastic, or metal, or any combinations thereof, for example. The housing HM may reliably protect the components of the display device 1000 housed in the interior space from external impact.

Referring now to FIGS. 1 to 2, a display panel DP and an optical element ES may be accommodated in a predetermined receiving space provided between the housing HM and the cover window WU.

The display panel DP may include a pixel PX for displaying an image and a drive unit 50, and the pixel PX is disposed in a display area DA and a component area EA. The display panel DP may include the front surface including the display area DA and a non-display area PA. In the embodiment, the display area DA and the component area EA may be areas which include pixels to display images, and at the same time areas where external inputs are detected by a touch sensor disposed on top of the pixels in the third direction DR3.

The transmissive area TA of the cover window WU may overlap at least a portion of the display area DA and component area EA of the display panel DP. In an embodiment, the transmissive area TA may overlap with the front surfaces of the display area DA and the component area EA, or may overlap at least a portion of the display area DA and the component area EA, for example. Accordingly, a user may view an image through the transmissive area TA and/or provide an external input based on the image. However, the disclosure is not limited thereto. In an embodiment, the area where the image is displayed and the area where the external input is detected may be separate from each other, for example.

The non-display area PA of the display panel DP may overlap at least partially the blocking area BA of the cover window WU. The non-display area PA may be the area covered by the blocking area BA. The non-display area PA may be next (adjacent) to the display area DA and may surround the display area DA. The non-display area PA does not display images, and may be arranged with drive circuit, drive wires, or the like to drive the display area DA. The non-display area PA may include a first peripheral area PA1 in which the display area DA is disposed on the outer side, and a second peripheral area PA2 including the drive unit 50, the connecting wires, and a bending area. In the embodiment of FIG. 2, the first peripheral area PA1 is disposed on three sides of the display area DA, and the second peripheral area PA2 is disposed on the remaining one side of the display area DA.

In the embodiment, a portion of the non-display area PA of the display panel DP may be curved. In this case, a portion of the non-display area PA may face the back surface of the display device 1000, thereby reducing the blocking area BA visible on the front surface of the display device 1000. In FIG. 2, the second peripheral area PA2 may be bent and assembled after being disposed on the back surface of the display area DA.

Further, the component area EA of the display panel DP may include a first component area EA1 and a second component area EA2. The first component area EA1 and the second component area EA2 may be at least partially surrounded by the display area DA. It is illustrated that the first component area EA1 and the second component area EA2 are spaced apart from each other, but may be at least partially connected, without limitation. The first component area EA1 and the second component area EA2 may be regions in which optical elements (refer to ES in FIG. 2; hereinafter referred to as components) utilizing infrared (“IR”), visible light, or sound are disposed therebelow.

The display area DA (hereinafter also referred to as the main display area) and the component area EA are formed with a plurality of light-emitting diodes (“LEDs”), and a plurality of pixel circuit units that generate and deliver light-emitting current to each of the plurality of LEDs. Here, one LED and one pixel circuit unit are also referred to as a pixel PX. In the display area DA and the component area EA, one pixel circuit unit and one LED may be formed one-to-one.

The first component area EA1 may include a transmissive portion through which light and/or sound may be transmitted and a display portion including a plurality of pixels. The transmissive portion is disposed between neighboring pixels and is formed with a layer through which light and/or sound may be transmitted. The transmissive portion may be disposed between neighboring pixels and, in some embodiments, a layer through which predetermined wavelengths of light (e.g., visible light) cannot be transmitted may also overlap the first component area EA1. The number of pixels (also referred to as resolution) per unit area of the pixels (also referred to as normal pixels) included in the display area DA may be the same as the number of pixels per unit area of the pixels (also referred to as first component pixels) included in the first component area EA1.

The second component area EA2 includes an area formed with a transparent layer that allows light to pass through (hereinafter also referred to as the light-transmissive area), in which the light-transmissive area does not have a conductive layer or a semiconductor layer, and may have a structure that does not block light by having a layer comprising a light-blocking material, e.g., a pixel defining layer and/or at least two color filters, formed to define an opening that overlaps a location corresponding to the second component area EA2. The number of pixels per unit area of the pixels (hereinafter also referred to as second component pixels) included in the second component area EA2 may be less than the number of pixels per unit area of the normal pixels included in the display area DA. As a result, the resolution of the second component pixel may be lower than the resolution of the normal pixel.

The drive unit 50 may be disposed (e.g., mounted) in the second peripheral area PA2, and may be disposed (e.g., mounted) on the bending portion or disposed on either side of the bending portion. The drive unit 50 may be in the form of a chip.

The drive unit 50 may be electrically connected to the display area DA and the component area EA to deliver electrical signals to the pixels in the display area DA and the component area EA. In an embodiment, the drive unit 50 may provide data signals to the pixels PX disposed in the display area DA, for example. In an alternative embodiment, the drive unit 50 may include a touch drive circuit and may be electrically connected to a touch sensor disposed in the display area DA and/or component area EA. In an alternative embodiment, the drive unit 50 may include various circuits in addition to the circuits described above, or may be designed to provide various electrical signals to the display area DA.

The display device 1000 may have a pad portion disposed at a distal end of the second peripheral area PA2, and may be electrically connected to a flexible printed circuit board (“FPCB”) including a driving chip by the pad portion. The drive chip disposed on the flexible printed circuit board may include various drive circuits for driving the display device 1000, connectors for power supply, or the like. In some embodiments, a rigid printed circuit board (“PCB”) may be used instead of the flexible printed circuit board.

The optical element ES may be disposed on a lower portion of the display panel DP. The optical element ES may include a first optical element ES1 overlapping the first component area EA1 and a second optical element ES2 overlapping the second component area EA2. The first optical element ES1 may use IR light, in which case the first component area EA1 may overlap the first component area EA1 by a layer that does not transmit light, such as visible light.

The first optical element ES1 may be an electronic element that utilizes light or sound. In an embodiment, the first optical element ES1 may be a sensor that receives and utilizes light, such as an IR sensor, a sensor that outputs and detects light or sound to measure a distance or recognize a fingerprint, a relatively small lamp that outputs light, a speaker that outputs sound, or the like, for example. In the case of an electronic element that utilizes light, it is possible to utilize light of various wavelength bands, such as visible light, IR light, ultraviolet light.

The second optical element ES2 may be at least one of a camera, an IR camera, a dot projector, an IR illuminator, and a time-of-flight sensor (“ToF sensor”).

In the embodiment, the optical element ES may further include a light detection sensor or a heat detection sensor. The optical element ES may detect an external object received through the front surface or provide a sound signal, such as a voice, to the outside through the front surface. The optical element ES may also include a plurality of configurations and is not limited to any the embodiment.

Referring now to FIG. 3, the display device 1000 may include a display panel DP, a power supply module PM, a first electronic module EM1, and a second electronic module EM2. The display panel DP, the power supply module PM, the first electronic module EM1, and the second electronic module EM2 may be electrically connected to each other.

In FIG. 3, a pixel PX and a touch sensor TS disposed in the display area DA among the configurations of the display panel DP are illustrated. The display panel DP may include a pixel PX and a touch sensor TS. The display panel DP may include the pixels PX that is an image-generating configuration and be externally visible to a user. In addition, the touch sensor TS may be disposed on top of the pixel PX and may detect an external input applied from the outside. The touch sensor TS may detect an external input provided to the cover window.

The power supply module PM may supply the power desired for the overall operation of the display device 1000. The power supply module PM may include a conventional battery module.

The first electronic module EM1 and the second electronic module EM2 may include various functional modules for operating the display device 1000. The first electronic module EM1 may be directly disposed (e.g., mounted) on a motherboard electrically connected to the display panel DP, or may be disposed (e.g., mounted) on a separate substrate and electrically connected to the motherboard via connectors (not shown) or the like.

The first electronic module EM1 may include a control module CM, a wireless communication module TM, an image input module IIM, an audio input module AIM, a memory MM, and an external interface IF. Some of the modules may not be disposed (e.g., mounted) on the motherboard, but may be electrically connected to the motherboard via flexible printed circuit boards connected to the motherboard.

The control module CM may control the overall operation of the display device 1000. The control module CM may be a microprocessor. In an embodiment, the control module CM activates or inactivates the display panel DP, for example. The control module CM may control other modules, such as an image input module IIM or an audio input module AIM, based on touch signals received from the display panel DP.

The wireless communication module TM may transmit/receive wireless signals to/from other terminals using Bluetooth or Wi-Fi lines. The wireless communication module TM may transmit/receive voice signals using a regular communication line. The wireless communication module TM includes a transmitting unit TM1 that modulates and transmits a signal to be transmitted, and a receiving unit TM2 that demodulates the received signal.

The image input module IIM may process the image signal and convert the processed image signal into image data that may be displayed on the display panel DP. The audio input module AIM may receive an external audio signal by a microphone in a recording mode, a voice recognition mode, or the like and convert the received audio signal into electrical audio data.

The external interface IF may serve as an interface to be connected to an external charger, wired/wireless data port, card socket (e.g., memory card, subscriber identity module/user identity module (“SIM/UIM”) card), or the like.

The second electronic module EM2 may include an audio output module AOM, a light-emitting module LM, a light-receiving module LRM, and a camera module CMM, at least some of which may be optical elements ES disposed on the back surface of the display panel DP as shown in FIG. 2. The optical element ES may include the light-emitting module LM, the light-receiving module LRM, and the camera module CMM. Further, the second electronic module EM2 may be directly disposed (e.g., mounted) on the motherboard, or may be disposed (e.g., mounted) on a separate substrate and electrically connected to the display panel DP via a connector (not shown), or may be electrically connected to the first electronic module EM1.

The audio output module AOM may convert audio data received from the wireless communication module TM or audio data stored in the memory MM and output the converted audio data to the outside.

The light-emitting module LM may generate and output light. The light-emitting module LM may output IR light. In an embodiment, the light-emitting module LM may include a LED element, for example. In an embodiment, the light-receiving module LRM may detect IR light, for example. The light-receiving module LRM may be activated when IR light of a predetermined level more is detected. The light-receiving module LRM may include a complementary metal-oxide-semiconductor (“CMOS”) sensor. After the IR light generated by the light-emitting module LM is output, the IR light may be reflected by an external object (e.g., a user's finger or face), and the reflected IR light may be incident on the light-receiving module LRM. The camera module CMM may photograph an image of the exterior.

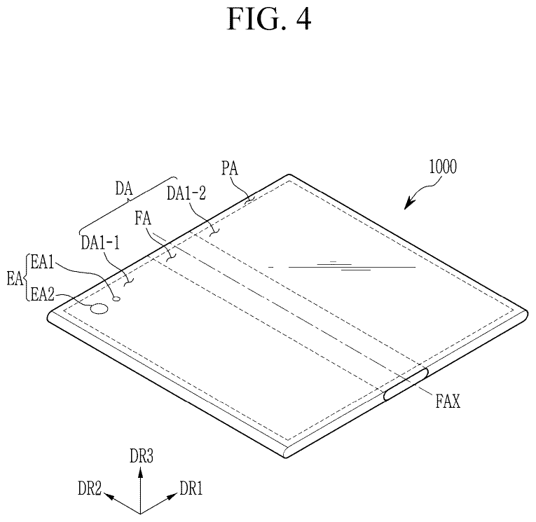

Hereinafter, a structure of a display device 1000 according to another embodiment will be described with reference to FIG. 4. FIG. 4 is a schematic perspective view of a display device according to another embodiment. The description of the same configuration as the components described above will be omitted, and the embodiment of FIG. 4 illustrates a foldable display device having a structure in which a display device 1000 is folded via a folding axis FAX.

Referring to FIG. 4, in the embodiment, the display device 1000 may be a foldable display device. The display device 1000 may be folded outwardly or inwardly with respect to the folding axis FAX. When the display device 1000 is folded outwardly with respect to the folding axis FAX, the display surfaces of the display device 1000 may be disposed at the outer sides in the third direction DR3, respectively, so that images may be displayed in both directions. When the display device 1000 is folded inwardly with respect to the folding axis FAX, the display surface may not be visible from the outside.

In the embodiment, the display device 1000 may include a display area DA, a component area EA, and a non-display area PA. The display area DA may be divided into a first-1 display area DA1-1, a second-1 display area DA1-2, and a folding area FA. The first-1 display area DA1-1 and the first-2 display area DA1-2 may be disposed on the left side and the right side, respectively, with respect to (or centered on) the folding axis FAX, and the folding area FA may be disposed between the first-1 display area DA1-1 and the first-2 display area DA1-2. In this case, when the display device 1000 is folded outwardly with respect to the folding axis FAX, the first-1 display area DA1-1 and the first-2 display area DA1-2 are disposed on opposite sides in the third direction DR3, and the image may be displayed in both directions. Furthermore, when the display device 1000 is folded inwardly with respect to the folding axis FAX, the first-1 display area DA1-1 and the first-2 display area DA1-2 may not be visible from the outside.

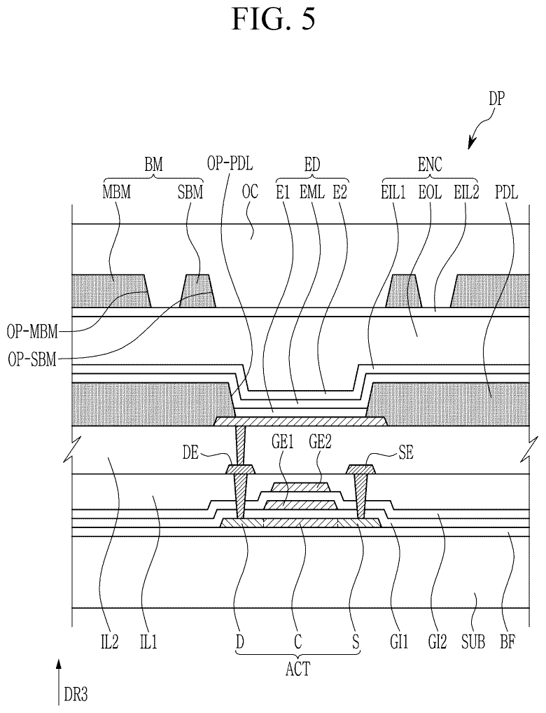

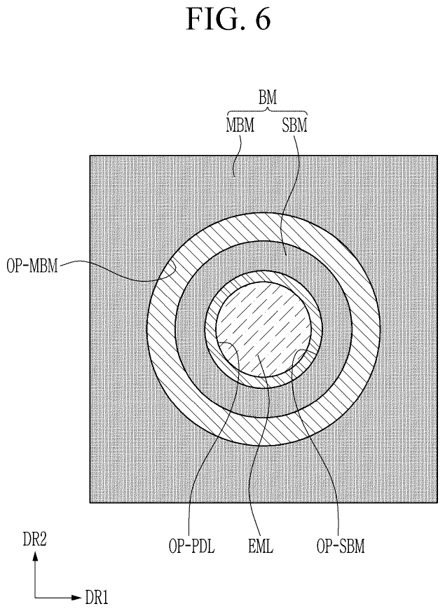

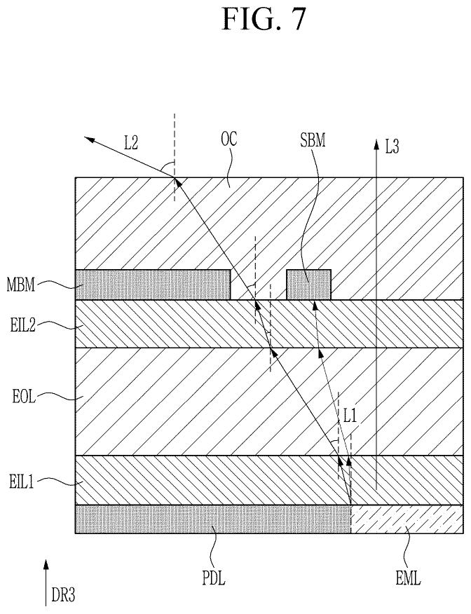

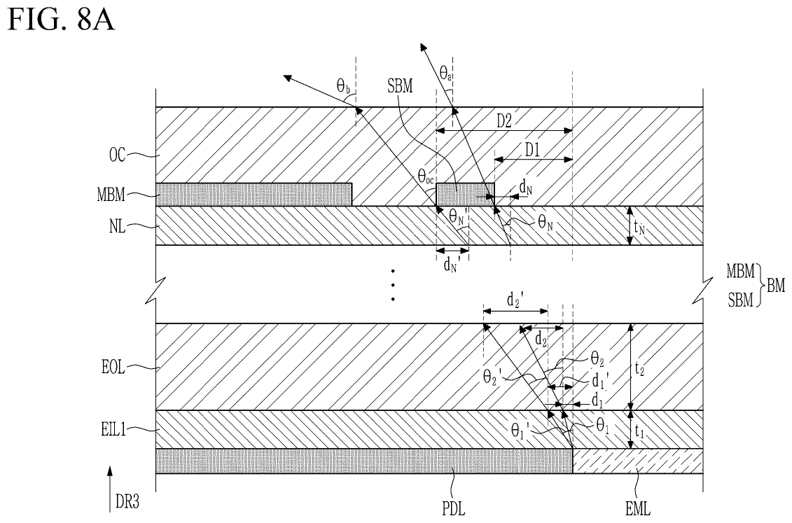

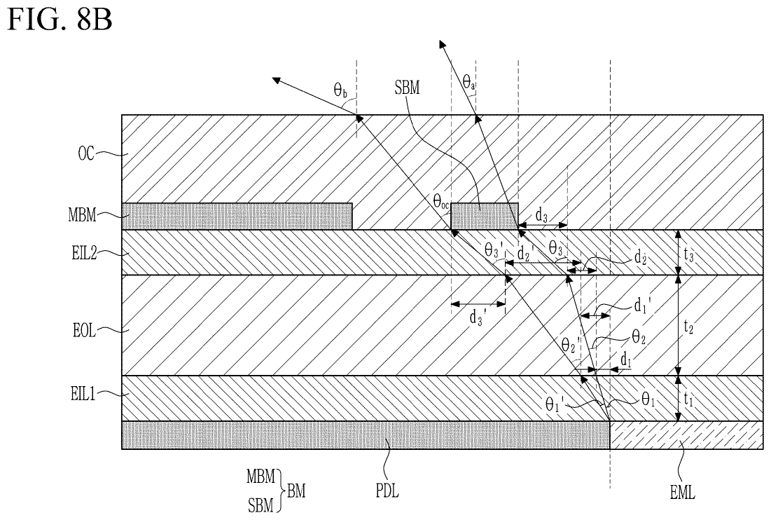

Hereinafter, a display device in an embodiment will be described with reference to FIGS. 5 to 8. FIG. 5 is a cross-sectional view of a display panel in the embodiment, FIG. 6 is a top plan view of some components of one pixel in the embodiment, and FIG. 7 and, FIGS. 8A and 8B are cross-sectional views of a traveling path of light in some areas.

First, referring to FIG. 5, a substrate SUB may include a material having rigid properties, such as glass, or a flexible material that may be bent, such as plastic and polyimide. The substrate SUB may extend in the first direction DR1 and the second direction DR2.

A buffer layer BF may be placed on top of the substrate SUB. The buffer layer BF may flatten the surface of the substrate SUB and block the penetration of impurity elements. The buffer layer BF may include an inorganic material, e.g., an inorganic insulating material, such as silicon nitride (SiNx), silicon oxide (SiOx), and silicon oxynitride (SiOxNy).

A semiconductor layer ACT may be disposed on top of the buffer layer BF. The semiconductor layer ACT of the display device in the embodiment may include amorphous silicon, polycrystalline silicon, or an oxide semiconductor.

The semiconductor layer ACT may include a channel region C, a source region S, and a drain region D, which are distinguished by whether they are doped with impurities or not. The source region S and the drain region D may be doped with impurities to have conductive properties corresponding to conductors.

A first gate insulating film GI1 may be disposed above the semiconductor layer ACT. A first gate insulating film GI1 may cover the semiconductor layer ACT and the substrate SUB. The first gate insulating film GI1 may include an inorganic insulating material, such as silicon nitride (SiNx), silicon oxide (SiOx), and silicon oxynitride (SiOxNy). The first gate insulating film GI1 may be a single layer or multilayer structure including different-phase inorganic insulating materials.

A gate electrode GE1 may be disposed on top of the first gate insulating film GI1. The gate electrode GE1 may include a metal or metal alloy, such as copper (Cu), molybdenum (Mo), aluminum (Al), silver (Ag), chromium (Cr), tantalum (Ta), and titanium (Ti). The gate electrode GE1 may be formed in a single layer or multiple layers. A region of the semiconductor layer ACT that overlaps the gate electrode GE1 in-plane may be a channel region C.

A second gate insulating film GI2 may be disposed above the gate electrode GE1. The second gate insulating film GI2 may include an inorganic insulating material, such as silicon nitride (SiNx), silicon oxide (SiOx), and silicon oxynitride (SiOxNy). The second gate insulating film GI2 may be a single layer or multilayer structure including different-phase inorganic insulating materials.

A capacitor electrode GE2 may be disposed on top of the second gate insulating film GI2. The capacitor electrode GE2 may overlap the gate electrode GE1 and form a capacitor.

A first insulating film IL1 may be disposed on the capacitor electrode GE2. The first insulating film IL1 may include an inorganic insulating material, such as silicon nitride (SiNx), silicon oxide (SiOx), and silicon oxynitride (SiOxNy). The first insulating film IL1 may be a single layer or multilayer structure including different-phase inorganic insulating materials.

A source electrode SE and a drain electrode DE may be disposed on the first insulating film IL1. The source electrode SE and the drain electrode DE are electrically connected to the source region S and the drain region D of the semiconductor layer ACT by openings defined in the first insulating film IL1, the second gate insulating film GI2, and the first gate insulating film GI1, respectively.

Accordingly, the semiconductor layer ACT, the gate electrode GE1, the source electrode SE, and the drain electrode DE form a single transistor. Depending on the embodiment, the transistor may include only the source region and the drain region of the semiconductor layer ACT instead of the source electrode SE and the drain electrode DE.

The source electrode SE and the drain electrode DE may include metals or metal alloys, such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode SE and the drain electrode DE may include a single layer or multiple layers. The source electrode SE and the drain electrode DE in the embodiment may include a triple layer including a top layer, a middle layer, and a bottom layer, in which the top layer and the bottom layer may include titanium (Ti) and the middle layer may include aluminum (Al).

A second insulating film IL2 may be disposed on the source electrode SE and the drain electrode DE. The second insulating film IL2 covers the source electrode SE and the drain electrode DE. The second insulating film IL2 may flatten the surface of the substrate SUB on which the transistors are disposed (e.g., mounted). The second insulating film IL2 may be an organic insulating film, and may include one or more materials selected from the group consisting of polyimide, polyamide, acrylic resin, benzocyclobutene, and phenolic resin.

A first electrode E1 may be disposed on top of the second insulating film IL2. The first electrode E1, also referred to as the anode electrode, may include a single layer or multiple layers including a transparent conductive oxide or metallic material. The transparent conductive oxide film may include indium tin oxide (“ITO”), poly-ITO, indium zinc oxide (“IZO”), indium gallium zinc oxide (“IGZO”), and indium tin zinc oxide (“ITZO”). The metal material may include silver (Ag), molybdenum (Mo), copper (Cu), gold (Au), aluminum (Al), or the like. In an embodiment, the first electrode E1 may have a three-layer structure of ITO/Ag/ITO, for example.

The first electrode E1 may be physically and electrically connected to the drain electrode DE through an opening in the second insulating film IL2. Accordingly, the first electrode E1 may receive an output current from the drain electrode DE to be delivered to the light-emitting layer EML.

A pixel defining layer PDL may be disposed on the first electrode E1 and the second insulating film IL2. The pixel defining layer PDL may overlap the edge of the first electrode E1 and be spaced apart from the center of the first electrode E1. The pixel defining layer PDL may compartmentalize the formation location of the light-emitting layer EML such that the light-emitting layer EML is disposed on the exposed top surface of the first electrode E1.

The pixel defining layer PDL may be an organic insulating film comprising one or more materials selected from the group consisting of polyimide, polyamide, acrylic resin, benzocyclobutene, and phenolic resin, and in some embodiments, the pixel defining layer PDL may be formed as a black pixel define layer including a black pigment.

The light-emitting layer EML may be disposed within an opening OP-PDL of the pixel defining layer PDL. The light-emitting layer EML may include an organic material that emits red, green, blue, or other colors of light. The light-emitting layer EML emitting red, green, or blue light may include a relatively low molecular weight or relatively high molecular weight organic material. Although FIG. 5 illustrates the light-emitting layer EML as a single layer, in practice, the light-emitting layer EML may also include auxiliary layers, such as an electron injection layer, an electron transport layer, a hole transport layer, and a hole injection layer on top and bottom of the light-emitting layer EML, the hole injection layer and the hole transport layer are disposed on the bottom of the light-emitting layer EML, and the electron transport layer and the electron injection layer are disposed on the top of the light-emitting layer EML.

The light-emitting layer EML in the embodiment may emit red light. A sub-blocking layer SBM, to be described later, may be disposed on the region emitting red light.

The second electrode E2 may be disposed on the pixel defining layer PDL and the light-emitting layer EML. The second electrode E2 is also referred to as a cathode electrode, and may be formed from a transparent conductive layer including indium tin oxide (“ITO”), indium zinc oxide (“IZO”), indium gallium zinc oxide (“IGZO”), and indium tin zinc oxide (“ITZO”). Furthermore, the second electrode E2 may have a translucent characteristic, and in this case, the second electrode E2 may form a microcavity together with the first electrode E1. According to the microcavity structure, the spacing and characteristics between the two electrodes allow light of a predetermined wavelength to be emitted to the top, resulting in display of red, green, or blue color.

The first electrode E1, the light-emitting layer EML, and the second electrode E2 may form a single light-emitting device ED.

An encapsulation layer ENC may be disposed on the second electrode E2. The encapsulation layer ENC may include at least one inorganic film and at least one organic film, and may have a triple-layer structure including a first inorganic encapsulation layer EIL1, an organic encapsulation layer EOL, and a second inorganic encapsulation layer EIL2, in the embodiment.

The encapsulation layer ENC may protect the light-emitting layer EML formed from the organic material from moisture, oxygen, or the like that may be introduced from the outside. Depending on the embodiment, the encapsulation layer ENC may include a structure in which inorganic and organic layers are stacked sequentially further.

A light-blocking layer BM may be disposed on top of the encapsulation layer ENC. The light-blocking layer BM may include or consist of a black colored organic material. The black organic material may include a light-blocking material.

The light-blocking layer BM in the embodiment may include a main light-blocking layer MBM and a sub-blocking layer SBM. The main light-blocking layer MBM and the sub-blocking layer SBM may be spaced apart from each other in plan and in cross-section.

As shown in FIG. 6, the main light-blocking layer MBM may have a circularly shaped opening OP-MBM. The sub-blocking layer SBM may be disposed within the opening OP-MBM of the main light-blocking layer MBM. The main light-blocking layer MBM may be shaped to surround the sub-blocking layer SBM.

The sub-blocking layer SBM may define a sub-opening OP-SBM. The sub-blocking layer SBM may be shaped to surround the light-emitting layer EML.

The opening OP-MBM of the main light-blocking layer MBM and the opening OP-SBM of the sub-blocking layer SBM in the embodiment may have a circular shape in plan, but are not limited thereto, and may of course be shaped in various ways.

Referring back to FIG. 5, a planarization layer OC covering the light-blocking layer BM is disposed on top of the light-blocking layer BM. The planarization layer OC is for planarizing the top surface of the display panel and may be a transparent organic insulating film including one or more materials selected from the group consisting of polyimide, polyamide, acrylic resin, benzocyclobutene, and phenolic resin.

The display device in the embodiment may include a sub-blocking layer SBM disposed in a region that emits red light. Red light emitted at relatively low angles may cause a reddish phenomenon in which the color of the display device looks red, and the sub-blocking layer may block the red light emitted at relatively low angles, thereby providing light with an appropriate color.

Hereinafter, the location and in-plane width of the sub-blocking layer SBM in the embodiment will be discussed in more detail with reference to FIGS. 7 and 8.

Referring first to FIG. 7, light emitted from the light-emitting layer EML may be emitted to the outside of the display device at various angles. The light emitted from the light-emitting layer EML may be refracted and emitted at the interface of the layers disposed between the light-emitting layer EML and the outside of the display device.

The light L1 emitted at a relative low angle (15 degrees to 30 degrees) in the third direction DR3 may be blocked by the sub-blocking layer SBM. Light L2 emitted at a relatively high angle (45 degrees to 60 degrees) in the third direction DR3 may be emitted between the sub-blocking layer SBM and the main light-blocking layer MBM. Further, the light L3 that is emitted in a substantially third direction DR3 may be emitted directly to the outside of the display device.

The display device in the embodiment may have a relatively high luminance of red light emitted at a relatively low angle, which may reduce the reddish phenomenon in which the display device is red-looking and provide a display device with an improved color.

The location where the sub-blocking layer SBM is disposed will be described in detail with reference to FIGS. 8A and 8B.

Referring first to FIG. 8A, a first distance D1 from an edge of the pixel defining layer PDL to an inner edge of the sub-blocking layer SBM may be determined through Equation 1 below. Further, a second distance D2 from the edge of the pixel defining layer PDL to an outer edge of the sub-blocking layer SBM may be determined through Equation 2 below.

$${\sum }_{n = N}^{1} {d}_{n} ( @ {θ}_{N + 1} = {θ}_{a} ) \qquad Equation 1$$

$${\sum }_{n = N}^{1} {d}_{n} ( @ {θ}_{N + 1} = {θ}_{b} ) \qquad Equation 2$$

In Equation 1, θₐ is a first angle of light emitted to the outside of the display device, and in Equation 2, θ_{b} is a second angle of light emitted to the outside of the display device. θₐ may be less than θ_{b}. θₐ and θ_{b} are the emission angles of the light for the third direction DR3, and are acute angles.

In this case, dₙ may be determined through following Equation 3.

$${d}_{n} = {t}_{n} \cdot tan {θ}_{n} \qquad Equation 3$$

In Equation 3, tₙ is a thickness of an n-th layer and θₙ may be determined through Equation 4 below.

$${θ}_{n} = {sin}^{- 1} ( sin {θ}_{n + 1} \cdot \frac{{n}_{n + 1}}{{n}_{1}} ) \qquad Equation 4$$

In Equation 4, ‘n’ may denote a refractive index, and ‘n’ (subscript of n) may correspond to the index ‘n’ in Equation 1 to Equation 3. Here, N may be determined by the number of all of layers between the pixel defining layer PDL and the light-blocking layer BM, and n_{N+1} is defined as 1. In an embodiment, when the number of layers between the pixel defining layer PDL and the light-blocking layer BM is three, the above value may be derived by substituting three for N, for example. The width of the sub-blocking layer SBM may be the value obtained by subtracting the value in Equation 1 from the value in Equation 2.

Referring to FIG. 8B, it will be described in detail the case where the first inorganic encapsulation layer EIL1, the organic encapsulation layer EOL, and the second inorganic encapsulation layer EIL2 are disposed between the light-blocking layer BM and the pixel defining layer PDL. The thickness t₁ of the first inorganic encapsulation layer EIL1, the thickness t₂ of the organic encapsulation layer EOL, and the thickness t₃ of the second inorganic encapsulation layer EIL2 may be determined with predetermined values.

First, it will be described the location and width of the sub-blocking layer SBM when it is desired to block light emitted from the red light emission region to the outside at an angle between θₐ and θ_{b}. In this case, θₐ may be less than θ_{b}. θₐ and θ_{b} are the acute angles to the third direction DR3.

Since three layers are disposed between the light-blocking layer BM and the pixel defining layer PDL, N may be three in Equations 1 to 4.

First, the location of the inner edge of the sub-blocking layer SBM will be described.

By using Equation 4, θ₃ is derived by substituting the refractive index of the second inorganic encapsulation layer EIL2 into n₃ and substituting θₐ into θ₄. n₄ is 1 according to Equation 4. d₃ is derived by substituting the derived θ₃ and the thickness t₃ of the second inorganic encapsulation layer EIL2 into Equation 3.

Then, θ₂ is derived by substituting the refractive index n₃ of the second inorganic encapsulation layer EIL2, the refractive index n₂ of the organic encapsulation layer EOL, and the above θ₃ into Equation 4. d₂ is derived by substituting the derived θ₂ and the thickness t₂ of the organic encapsulation layer EOL into Equation 3.

Then, θ₁ is derived by substituting the refractive index n₂ of the organic encapsulation layer EOL, the refractive index n₁ of the first inorganic encapsulation layer EIL1, and the above θ₂ into Equation 4. d₁ is derived by substituting the derived θ₁ and the thickness t₁ of the first inorganic encapsulation layer EIL1 into Equation 3.

To block light emitted at an angle of θₐ, the inner edge of the sub-blocking layer SBM may be spaced from the edge of the pixel defining layer PDL by d₁+d₂+d₃.

Next, the location of the outer edge of the sub-blocking layer SBM will be described.

By using Equation 4, θ₃′ is derived by substituting the refractive index of the second inorganic encapsulation layer EIL2 into n₃ and substituting θ_{b} into θ₄. d₃′ is derived by substituting the derived θ_{3′} and the thickness t₃ of the second inorganic encapsulation layer EIL2 into Equation 3.

Then, θ_{2′} is derived by substituting the refractive index n₃ of the second inorganic encapsulation layer EIL2, the refractive index n₂ of the organic encapsulation layer EOL, and the above θ_{3′} into Equation 4. d₂′ is derived by substituting the derived θ_{2′} and the thickness t₂ of the organic encapsulation layer EOL into Equation 3.

Then, θ_{1′} is derived by substituting the refractive index n₂ of the organic encapsulation layer EOL, the refractive index n₁ of the first inorganic encapsulation layer EIL1, and the above θ_{2′} into Equation 4. d_{1′} is derived by substituting the derived Or and the thickness t₁ of the first inorganic encapsulation layer EIL1 into Equation 3.

To block light emitted at an angle of θ_{b}, the sub-blocking layer SBM may be spaced from the edge of the pixel defining layer PDL by d₁+d₂+d₃.

Therefore, when it is desired to block light emitted at an angle between θa to θb among the light emitted from the red light emission region to the outside, the inner edge of the sub-blocking layer SBM may be disposed at a location spaced from the pixel defining layer PDL by a distance d₁+d₂+d₃. The outer edge of the sub-blocking layer SBM may also be disposed at a location spaced apart from the pixel defining layer PDL by a distance d_{1′}+d_{2′}+d_{3′}.

The width of the sub-blocking layer SBM may be (d_{1′}+d_{2′}+d_{3′})−(d₁+d₂+d₃). That is, the width of the sub-blocking layer may be the value obtained by subtracting the value in Equation 1 from the value in Equation 2.

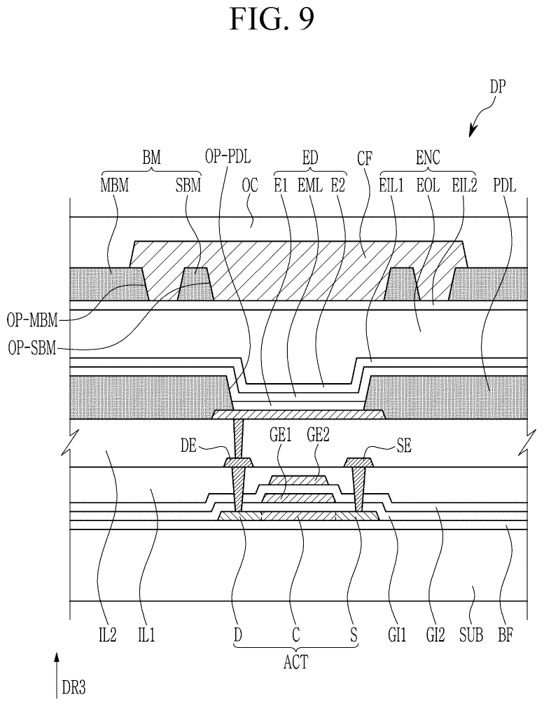

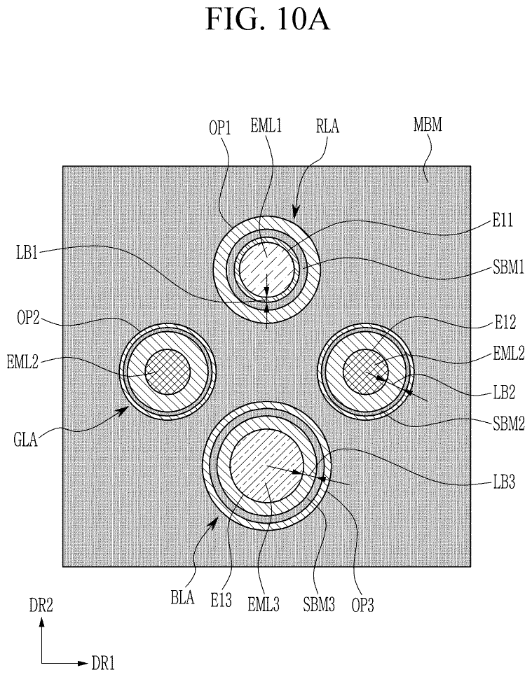

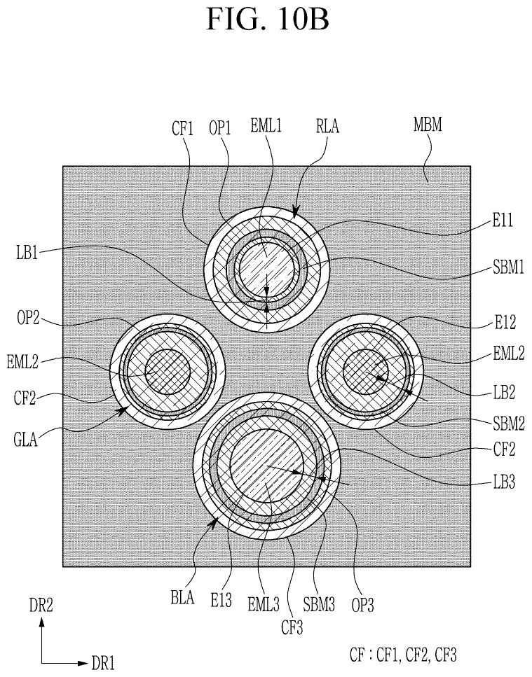

Hereinafter, a display panel according to another embodiment will be described with reference to FIGS. 9, 10A, and 10B. FIG. 9 is a cross-sectional view of a display panel in an embodiment, and FIGS. 10A and 10B are each a top plan view of some pixels in the embodiment. A description of components that are identical to the components described above will be omitted.

Referring now to FIG. 9, the display device in the embodiment may further include a color filter CF. The color filter CF may be any one of a red color filter that transmits red light, a green color filter that transmits green light, and a blue color filter that transmits blue light.

The color filter CF may overlap the first electrode E1 of the LED. The light emitted from the light-emitting layer EML may be emitted while changing to a corresponding color as it passes through the color filter, so that the light emitted from the light-emitting layer EML may all have the same color. However, it is also possible for the light-emitting layer EML to emit different colors of light, which may be passed through a color filter of the same color to enhance the displayed color.

Depending on the embodiment, the color filter CF may be replaced by a color conversion layer, or may further include a color conversion layer. The color conversion layer may include quantum dots.

The color filter CF may overlap the light-blocking layer BM. The color filter CF may overlap at least a portion of the sub-blocking layer SBM and the main light-blocking layer MBM. The color filter CF may completely cover the top surface and the lateral surface of the sub-blocking layer SBM. The color filter CF may cover a portion of the main light-blocking layer MBM. The color filter CF may fill the space spaced between the main light-blocking layer MBM and the sub-blocking layer SBM.

Referring now to FIG. 10A, the display panel in the embodiment may include a red light-emitting area RLA, a green light-emitting area GLA, and a blue light-emitting area BLA. The main light-blocking layer BM may define a first opening OP1, a second opening OP2, and a third opening OP3 overlapping each of the red light-emitting area RLA, the green light-emitting area GLA, and the blue light-emitting area BLA.

The display panel in the embodiment may include a first sub-blocking layer SBM1 disposed within the first opening OP1, a second sub-blocking layer SBM2 disposed within the second opening OP2, and a third sub-blocking layer SBM3 disposed within the third opening OP3.

Each of the first sub-blocking layer SBM1, the second sub-blocking layer SBM2, and the third sub-blocking layer SBM3 may have different sizes. The location and width of each of the first sub-blocking layer SBM1, the second sub-blocking layer SBM2, and the third sub-blocking layer SBM3 may be determined through foregoing Equations 1 to 4.

The widths of the first sub-blocking layer SBM1, the second sub-blocking layer SBM2, and the third sub-blocking layer SBM3 may each be different.

To adjust the color of the display device, the emitted red light, green light, and blue light may need to be controlled at different angles. In an embodiment, light emitted at relatively low angles may be blocked in areas that emit red light, while light emitted at relatively high angles may be blocked in areas that emit blue and green light, for example. The location and width of the sub-blocking layer may be adjusted according to the angle of light emission to be blocked. The location and width of each sub-blocking layer may be derived by substituting the emission angle to be controlled into Equation 1 to Equation 4.

The distance from the edge of the pixel defining layer to the inner edge of each sub-blocking layer may vary. A first distance LB1 from a first edge E11 of the pixel defining layer to the inner edge of the first sub-blocking layer SBM1, a second distance LB2 from a second edge E12 of the pixel defining layer to the inner edge of the second sub-blocking layer SBM2, and a third distance LB3 from a third edge E13 of the pixel defining layer to the inner edge of the third sub-blocking layer SBM3 may be different from one another. The first distance LB1 may be less than the second distance LB2 and the third distance LB3.

Referring now to FIG. 10B, the display device in the embodiment may further include a color filter CF. The color filters CF1, CF2, and CF3 may be any one of a red color filter CF1 that transmits red light, a green color filter CF2 that transmits green light, and a blue color filter CF3 that transmits blue light.

The red color filter CF1 may cover a red light-emitting area RLA. The green color filter CF2 may cover a green light-emitting area GLA. The blue color filter CF3 may cover a blue light-emitting area BLA. In the specification, the embodiment in which the red, green, and blue color filters CF1, CF2, and CF3 do not overlap is illustrated, but some of the plurality of color filters may overlap each other.

The color filters CF1, CF2, and CF3 may overlap the light-emitting layers EML1, EML2, and EML3 of the LEDs. The light emitted from the light-emitting layers EML1, EML2, and EML3 may be emitted while changing to corresponding colors as it passes through the color filters CF1, CF2, and CF3, so that the light emitted from the light-emitting layers EML1, EML2, and EML3 may all have the same color. However, it is also possible for the light-emitting layers EML1, EML2, and EML3 to emit different colors of light, which may be passed through the color filters CF1, CF2, and CF3 of the same color to enhance the displayed color.

Depending on the embodiment, the color filters CF1, CF2, and CF3 may be replaced by a color conversion layer, or may further include a color conversion layer. The color conversion layer may include quantum dots.

The color filters CF1, CF2, and CF3 may overlap at least a portion of the main light-blocking layer MBM. Furthermore, each of the color filters CF1, CF2, and CF3 may overlap a corresponding sub-blocking layer SBM1, SBM2, or SBM3 for each region. The first color filter CF1 may overlap the first sub-blocking layer SBM1. The second color filter CF2 may overlap the second sub-blocking layer SBM2. The third color filter CF3 may overlap the third sub-blocking layer SBM3.

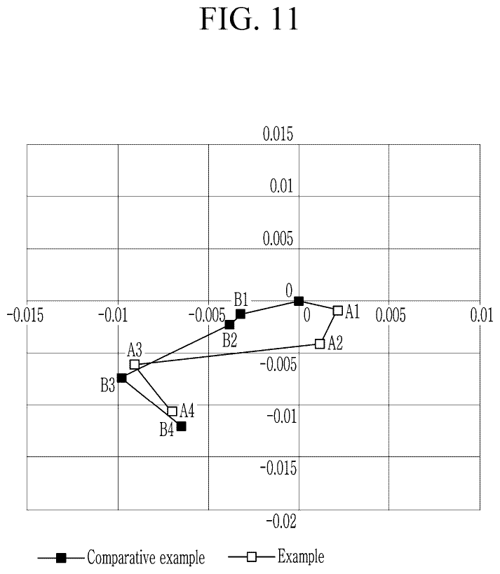

Hereinafter, an Embodiment and a Comparative example will be described with reference to FIG. 11. FIG. 11 is a WAD graph according to an Embodiment and a Comparative example.

An Embodiment relates to a display panel including a main light-blocking layer and a sub-blocking layer, and a Comparative example relates to a display panel including only a main light-blocking layer. In particular, the example includes a sub-blocking layer having a distance from an inner edge of the sub-blocking layer to a pixel defining layer in a red light-emitting area of 1 micrometer, and a distance from an outer edge of the sub-blocking layer to the pixel defining layer of 2 micrometers. The example includes a sub-blocking layer having a distance from an inner edge of the sub-blocking layer to a pixel defining layer in a green light-emitting area of 6 micrometer, and a distance from an outer edge of the sub-blocking layer to the pixel defining layer of 7 micrometers. The example includes a sub-blocking layer having a distance from an inner edge of the sub-blocking layer to a pixel defining layer in a blue light-emitting area of 1.5 micrometer, and a distance from an outer edge of the sub-blocking layer to the pixel defining layer of 2.5 micrometers.

In the graphs according to the Comparative example and the Embodiment, A1 and B1 are the color coordinates of light emitted at 15 degrees, A2 and B2 are the color coordinates of light emitted at 30 degrees. A3 and B3 are the color coordinates of light emitted at 45 degrees, and A4 and B4 are the color coordinates of light emitted at 60 degrees.

It has been confirmed that at 45 degrees and 60 degrees, the Comparative example and the Embodiment have nearly similar colors, but at 15 degrees and 30 degrees, the Embodiment exhibits colors with significantly reduced reddishness compared to the Comparative example.

It has been confirmed that when the sub-blocking layer is applied to the red light-emitting area in accordance with the Embodiment, red light emitted at relatively low angles is blocked, the reddish phenomenon is reduced, and a display device with a color desired by the user is provided.

A display device in an embodiment may be applied to various electronic devices. An electronic device in an embodiment may include the display device, and may further include modules or devices having additional functions other than the display device.

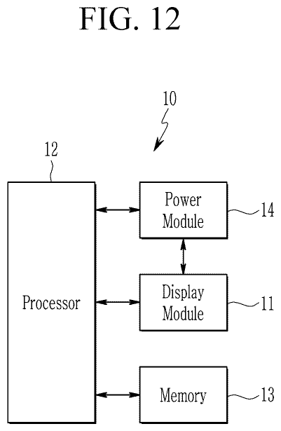

FIG. 12 is a block diagram of an electronic device. Referring to FIG. 12, the electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for operations of the processor 12 or the display module 11. When the processor 12 executes an application stored in the memory 13, video data signals and/or input control signals are transmitted to the display module 11, and the display module 11 may process the received signals to output video information through the display screen.

The power module 14 may include a power supply module such as a power adapter or battery device, and a power conversion module that converts the power supplied by the power supply module to generate the power desired for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. In an embodiment, the display device may include the display module 11, while the processor 12, memory 13, and power module 14 may be provided in a form of other devices within the electronic device 10 that are not part of the display device, for example.

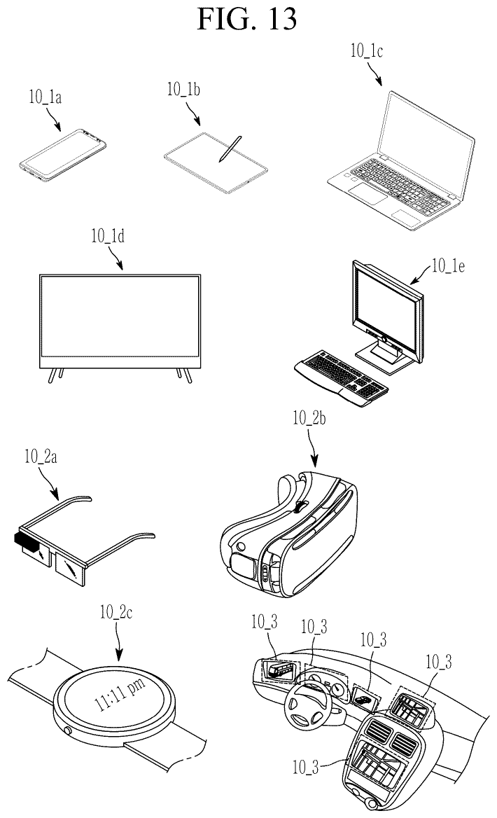

FIG. 13 shows schematic diagrams of electronic devices according to various embodiments.

Referring to FIG. 13, various electronic devices with the display device in the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, center information display (“CID”), room mirror displays, and so on.

Although an embodiment of the disclosure has been described in detail, the scope of the disclosure is not limited by the embodiment. Various changes and modifications using the basic concept of the disclosure defined in the accompanying claims by those skilled in the art shall be construed to belong to the scope of the disclosure.

What is claimed is:

1. A display device comprising:
a substrate;
a transistor disposed on the substrate;
a first electrode electrically connected with the transistor;
a pixel defining layer disposed on the first electrode;
a light-emitting layer disposed in an opening of the pixel defining layer;
a second electrode disposed on the light-emitting layer;
an encapsulation layer disposed on the second electrode; and
a main light-blocking layer and a sub-blocking layer disposed on the encapsulation layer,
wherein a first distance between an inner edge of the sub-blocking layer and an edge of the pixel defining layer satisfies Equation 1, and
a second distance between an outer edge of the sub-blocking layer and the edge of the pixel defining layer satisfies Equation 2,
$${\sum }_{n = N}^{1} {d}_{n} ( @ {θ}_{N + 1} = {θ}_{a} ) \qquad Equation 1$$
$${\sum }_{n = N}^{1} {d}_{n} ( @ {θ}_{N + 1} = {θ}_{a} ) {\sum }_{n = N}^{1} {d}_{n} ( @ {θ}_{N + 1} = {θ}_{b} ) \qquad Equation 2$$
in Equation 1, θₐ is a first angle of light emitted outwardly from the display device,
in Equation 2, θ_{b} is a second angle of light emitted outwardly from the display device,
the first angle is less than the second angle,
in Equations 1 and 2, N is a number of layers disposed between the pixel defining layer and the main light-blocking layer,
dₙ in Equation 1 and Equation 2 is determined through following Equation 3,
$${d}_{n} = {t}_{n} \cdot tan {θ}_{n} \qquad Equation 3$$
in Equation 3, tₙ is a thickness of an n-th layer and θₙ is determined through following Equation 4, and
$${θ}_{n} = {sin}^{- 1} ( sin {θ}_{n + 1} \cdot \frac{{n}_{n + 1}}{{n}_{1}} ) \qquad Equation 4$$
where n_{N+1} is 1 in Equation 4.

2. The display device of claim 1, wherein:
the main light-blocking layer and the sub-blocking layer are spaced apart from each other, and
a planar shape of an opening of the main light-blocking layer and a planar shape of the sub-blocking layer are circular.

3. The display device of claim 2, wherein:
the main light-blocking layer surrounds the sub-blocking layer.

4. The display device of claim 1, wherein:
the display device includes a red light-emitting area, a green light-emitting area, and a blue light-emitting area, and
the sub-blocking layer overlaps the red light-emitting area.

5. The display device of claim 1, wherein:
the display device includes a red light-emitting area, a green light-emitting area, and a blue light-emitting area, and
the sub-blocking layer includes at least one of
a first sub-blocking layer overlapping the red light-emitting area,
a second sub-blocking layer overlapping the green light-emitting area, and
a third sub-blocking layer overlapping the blue light-emitting area.

6. The display device of claim 5, wherein:
the sub-blocking layer includes the first sub-blocking layer, the second sub-blocking layer, and the third sub-blocking layer.

7. The display device of claim 6, wherein:
a third distance from an end of the pixel defining layer to an inner edge of the first sub-blocking layer in the red light-emitting area is less than a fourth distance from an end of the pixel defining layer to an inner edge of the second sub-blocking layer in the green light-emitting area.

8. The display device of claim 6, wherein:
a fifth distance from an end of the pixel defining layer to an inner edge of the first sub-blocking layer in the red light-emitting area is less than a sixth distance from an end of the pixel defining layer to an inner edge of the third sub-blocking layer in the blue light-emitting area.

9. The display device of claim 1, further comprising:
a color filter disposed on the main light-blocking layer.

10. The display device of claim 9, wherein:
the color filter fills a spaced space between the main light-blocking layer and the sub-blocking layer.

11. A display device comprising:
a substrate;
a transistor disposed on the substrate;
a first electrode electrically connected with the transistor;
a pixel defining layer disposed on the first electrode;
a light-emitting layer disposed in an opening of the pixel defining layer;
a second electrode disposed on the light-emitting layer;
an encapsulation layer disposed on the second electrode; and
a main light-blocking layer and a sub-blocking layer disposed on the encapsulation layer,
wherein the sub-blocking layer is disposed within an opening of the main light-blocking layer,
planar shapes of the opening of the main light-blocking layer, the sub-blocking layer, and an opening of the pixel defining layer are circular, and
the light-emitting layer emits red light.

12. The display device of claim 11, wherein:
a first distance between an inner edge of the sub-blocking layer and an edge of the pixel defining layer satisfies Equation 1, and
a second distance between an outer edge of the sub-blocking layer and the edge of the pixel defining layer satisfies Equation 2,
$${\sum }_{n = N}^{1} {d}_{n} ( @ {θ}_{N + 1} = {θ}_{a} ) \qquad Equation 1$$
$${\sum }_{n = N}^{1} {d}_{n} ( @ {θ}_{N + 1} = {θ}_{b} ) \qquad Equation 2$$
in Equation 1, θₐ is a first angle of light emitted outwardly from the display device,
in Equation 2, θ_{b} is a second angle of light emitted outwardly from the display device,
the first angle is less than the second angle,
in Equations 1 and 2, N is a number of layers disposed between the pixel defining layer and the main light-blocking layer,
dₙ in Equation 1 and Equation 2 is determined through following Equation 3,
$${d}_{n} = {t}_{n} \cdot tan {θ}_{n} \qquad Equation 3$$
in Equation 3, tₙ is a thickness of an n-th layer and θₙ is determined through following Equation 4, and
$${θ}_{n} = {sin}^{- 1} ( sin {θ}_{n + 1} \cdot \frac{{n}_{n + 1}}{{n}_{1}} ) \qquad Equation 4$$
where n_{N+1} is 1 in Equation 4.

13. The display device of claim 12, wherein:
the main light-blocking layer surrounds the sub-blocking layer.

14. The display device of claim 11, wherein:
the display device includes a red light-emitting area, a green light-emitting area, and a blue light-emitting area.

15. The display device of claim 14, wherein:
the sub-blocking layer includes at least one of
a first sub-blocking layer overlapping the red light-emitting area,
a second sub-blocking layer overlapping the green light-emitting area, and
a third sub-blocking layer overlapping the blue light-emitting area.

16. The display device of claim 15, wherein:
the sub-blocking layer includes the first sub-blocking layer, the second sub-blocking layer, and the third sub-blocking layer.

17. The display device of claim 16, wherein:
a third distance from an end of the pixel defining layer to an inner edge of the first sub-blocking layer in the red light-emitting area is less than a fourth distance from an end of the pixel defining layer to an inner edge of the second sub-blocking layer in the green light-emitting area.

18. The display device of claim 16, wherein:
a fifth distance from an end of the pixel defining layer to an inner edge of the first sub-blocking layer in the red light-emitting area is less than a sixth distance from an end of the pixel defining layer to an inner edge of the third sub-blocking layer in the blue light-emitting area.

19. An electronic device comprising a display device comprising:
a substrate;
a transistor disposed on the substrate;
a first electrode electrically connected with the transistor;
a pixel defining layer disposed on the first electrode;
a light-emitting layer disposed in an opening of the pixel defining layer;
a second electrode disposed on the light-emitting layer;
an encapsulation layer disposed on the second electrode; and
a main light-blocking layer and a sub-blocking layer disposed on the encapsulation layer,
wherein a first distance between an inner edge of the sub-blocking layer and an edge of the pixel defining layer satisfies Equation 1, and
a second distance between an outer edge of the sub-blocking layer and the edge of the pixel defining layer satisfies Equation 2,
$${\sum }_{n = N}^{1} {d}_{n} ( @ {θ}_{N + 1} = {θ}_{a} ) \qquad Equation 1$$
$${\sum }_{n = N}^{1} {d}_{n} ( @ {θ}_{N + 1} = {θ}_{b} ) \qquad Equation 2$$
in Equation 1, θₐ is a first angle of light emitted outwardly from the display device,
in Equation 2, θ_{b} is a second angle of light emitted outwardly from the display device,
the first angle is less than the second angle,
in Equations 1 and 2, N is a number of layers disposed between the pixel defining layer and the main light-blocking layer,
dₙ in Equation 1 and Equation 2 is determined through following Equation 3,
$${d}_{n} = {t}_{n} \cdot tan {θ}_{n} \qquad Equation 3$$
in Equation 3, tₙ is a thickness of an n-th layer and θₙ is determined through following Equation 4, and
$${θ}_{n} = {sin}^{- 1} ( sin {θ}_{n + 1} \cdot \frac{{n}_{n + 1}}{{n}_{1}} ) \qquad Equation 4$$
in Equation 4, n_{N+1} is 1.

20. The electronic device of claim 19, wherein the electronic device is a smartphone, a television, a monitor, a tablet, an electric vehicle, a mobile phone, a tablet personal computer, a mobile communication terminal, an electronic notebook, an electronic book, a portable multimedia player, a navigation device, an ultra-mobile PC, a laptop computer, a billboard, an Internet of Things device, a smartwatch, a watch phone, or a head-mounted display.
